(19) United States
(12) Patent Application Publication
(10) Pub. No.: US 2023/0028244 A1
(43) Pub. Date: Jan. 26, 2023

(54) RESIST TOPCOAT COMPOSITION, AND METHOD OF FORMING PATTERNS USING THE COMPOSITION

(71) Applicants: SAMSUNG SDI CO., LTD., Yongin-si (KR); SAMSUNG ELECTRONICS CO., LTD., Suwon-si (KR)

(72) Inventors: Ran NAMGUNG, Suwon-si (KR); Daeseok SONG, Suwon-si (KR); Minsoo KIM, Suwon-si (KR); Hyeon PARK, Suwon-si (KR); Minki CHON, Suwon-si (KR); Jun Soo KIM, Hwaseong-si (KR); Hyun-Woo KIM, Seongnam-si (KR); Hyun-Ji SONG, Anyang-si (KR); Young Joo CHOI, Hwaseong-si (KR); Suk-Koo HONG, Hwaseong-si (KR)

(21) Appl. No.: 17/749,899

(22) Filed: May 20, 2022

(30) Foreign Application Priority Data
Jul. 1, 2021 (KR) 10-2021-0086515

(51) Int. Cl. G03F 7/11; C09D 133/16; G03F 7/16

(52) U.S. Cl. CPC G03F 7/11; C09D 133/16; G03F 7/168

(57) ABSTRACT

A resist topcoat composition and a method of forming patterns using the resist topcoat composition are provided. The resist topcoat resist topcoat composition includes an acrylic polymer including a structural unit containing a hydroxy group and a fluorine; at least one acid compound selected from a sulfonic acid compound containing at least one fluorine, a sulfonimide compound containing at least one fluorine, and a carboxylic acid compound containing at least one fluorine; and a solvent.

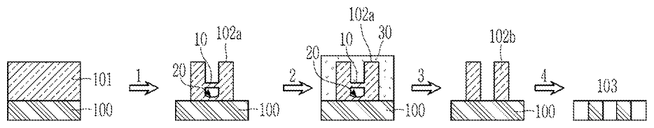

### CROSS-REFERENCE TO RELATED APPLICATION

This application claims priority to and the benefit of Korean Patent Application No. 10-2021-0086515, filed in the Korean Intellectual Property Office on Jul. 1, 2021, the entire content of which is incorporated herein by reference.

### BACKGROUND

### 1. Field

One or more aspects of embodiments of the present disclosure relate to a resist topcoat composition, and a method of forming patterns using the same.

### 2. Description of the Related Art

Recently, the semiconductor industry has developed an ultrafine technique for providing a pattern of several to several tens of nanometers in size (e.g., in nanometer scale). Such ultrafine technique needs effective (or suitable) lithographic techniques.

An example lithographic technique involves forming a material layer on a semiconductor substrate, coating a photoresist layer thereon, exposing and developing the photoresist layer to form a photoresist pattern, and then etching the material layer using the photoresist pattern as a mask.

As lithographic techniques are developed, a degree of pattern integration is increasing, and materials and technologies for solving various problems occurring in this process are required (or desired). In particular, when a photoresist is patterned using extreme ultraviolet (EUV) as a light source, a high-resolution pattern may be realized, but single line open (SLO) defects may occur randomly on the pattern due to photon shot noise. These SLO defects may lower yield, and thus improved technology development is required (or desired).

### SUMMARY

One or more aspects of embodiments of the present disclosure are directed toward a resist topcoat composition capable of not only realizing high-resolution patterns, but also removing single line open (SLO) defects to improve yield.

One or more aspects of embodiments of the present disclosure are directed toward a method of forming patterns using the resist topcoat composition.

In one or more embodiments, a resist topcoat composition includes an acrylic polymer including a structural unit containing a hydroxy group and a fluorine; at least one acid compound selected from a sulfonic acid compound containing at least one fluorine, a sulfonimide compound containing at least one fluorine, and a carboxylic acid compound containing at least one fluorine; and a solvent.

The acrylic polymer and the acid compound may be included in a weight ratio of about 3:1 to about 30:1.

A total weight of the acrylic polymer and the acid compound may be in an amount of about 0.1 wt % to about 10 wt % based on the total weight of the resist topcoat composition.

The acrylic polymer may include a structural unit represented by Chemical Formula 1:

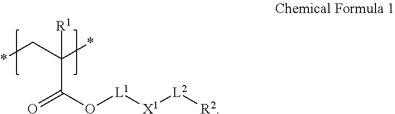

In Chemical Formula 1,

R¹ may be hydrogen or a substituted or unsubstituted C1 to C10 alkyl group,

R² may be hydrogen, a fluorine, a hydroxy group, or a substituted or unsubstituted C1 to C20 alkyl group,

L¹ and L² may be each independently a single bond, or a substituted or unsubstituted C1 to C10 alkylene group,

X¹ may be a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group),

R², L¹, and L² may together include a fluorine and a hydroxy group, and

* is a linking point (e.g., a binding site).

The acrylic polymer may include a structural unit represented by Chemical Formula 2:

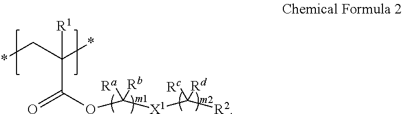

In Chemical Formula 2,

R¹ may be hydrogen or a substituted or unsubstituted C1 to C10 alkyl group,

R^{a}, R^{b}, R^{c}, R^{d}, and R² may be each independently hydrogen, a fluorine, a hydroxy group, or a substituted or unsubstituted C1 to C20 alkyl group,

m1 and m2 may be each independently an integer from 1 to 10,

X¹ may be a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group),

R^{a}, R^{b}, R^{c}, R^{d}, and R² may together include a fluorine and a hydroxy group, and

* is a linking point.

The structural unit containing the hydroxy group and fluorine may be selected from Group I:

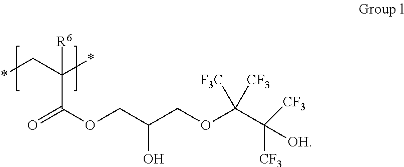

In Group I, R³ to R⁶ may be each independently hydrogen or a methyl group, and * is a linking point.

A weight average molecular weight of the acrylic polymer may be about 1,000 g/mol to about 50,000 g/mol.

The acid compound may be at least one of compounds represented by Chemical Formula 3 to Chemical Formula 6:

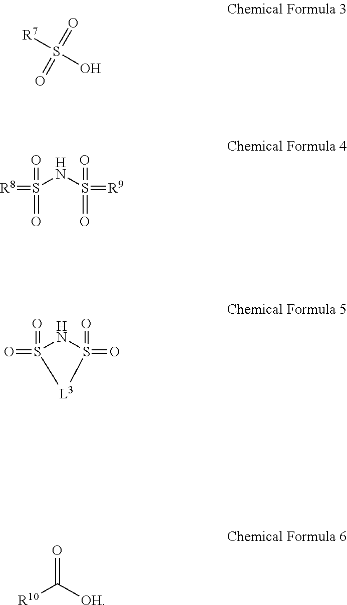

In Chemical Formula 3 to Chemical Formula 6,

R⁷ to R¹⁰ may be each independently a fluorine, a C1 to C20 alkyl group substituted with at least one fluorine, a C2 to C20 alkenyl group substituted with at least one fluorine, a C2 to C20 alkynyl group substituted with at least one fluorine, a C3 to C20 cycloalkyl group substituted with at least one fluorine, a C3 to C20 cycloalkenyl group substituted with at least one fluorine, a C3 to C20 cycloalkynyl group substituted with at least one fluorine, a C6 to C20 aryl group substituted with at least one fluorine, or a C1 to C20 heteroaryl group substituted with at least one fluorine, and

L³ may be a C1 to C10 alkylene group substituted with at least one fluorine, a C3 to C20 cycloalkylene group substituted with at least one fluorine, a C6 to C20 arylene group substituted with at least one fluorine, or a C1 to C20 heteroarylene group substituted with at least one fluorine.

For example, the acid compound may be at least one of the compounds of Group II:

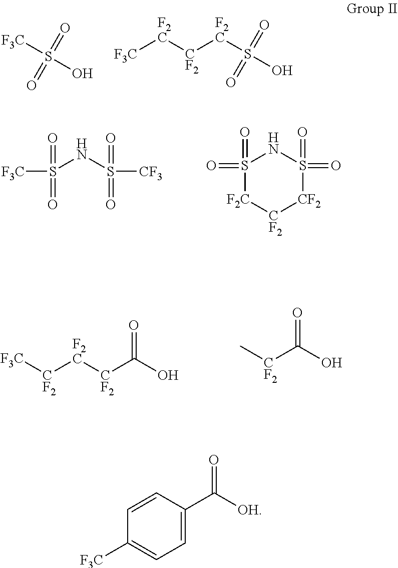

The solvent may be an ether-based solvent represented by Chemical Formula 7:

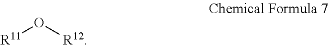

In Chemical Formula 7,

R¹¹ and R¹² may be each independently a substituted or unsubstituted C3 to C20 alkyl group.

The ether-based solvent may be selected from diisopropylether, dipropylether, diisoamylether, diamylether, dibutylether, diisobutylether, di-sec-butylether, dihexylether, bis(2-ethylhexyl)ether, didecylether, diundecylether, didodecylether, ditetradecylether, hexadecylether, butylmethylether, butylethylether, butylpropylether, tert-butylmethylether, tert-butylethylether, tert-butylpropylether, di-tert-butylether, cyclopentylmethylether, cyclohexylmethylether, cyclopentylethylether, cyclohexylethylether, cyclopentylpropylether, cyclopentyl-2-propylether, cyclohexylpropylether, cyclohexyl-2-propylether, cyclopentylbutylether, cyclopentyl-tert-butylether, cyclohexylbutylether, cyclohexyl-tert-butylether, 2-octanone, 4-heptanone, and a combination thereof.

In one or more other embodiments, a method of forming patterns includes forming a preliminary photoresist pattern on a substrate, coating the aforementioned resist topcoat composition (e.g., the resist topcoat composition of the present embodiments) on the preliminary photoresist pattern, drying and heating the substrate on which the resist topcoat composition is coated to form a topcoat, and spraying a rinse solution on the substrate coated with the topcoat to remove the topcoat.

The heating of the substrate coated with the resist topcoat composition may be performed at a temperature of about 100° C. to about 500° C.

The resist topcoat composition according to one or more embodiments has excellent solubility in a solvent having low reactivity with respect to photoresist, and thus may effectively (or suitably) remove SLO defects without loss (or substantially without loss) of photoresist fine patterns.

Because the SLO defects may be removed by a relatively simple process, it is advantageous in terms of process economy. Accordingly, the resist topcoat composition according to one or more embodiments or a pattern prepared therefrom may be advantageously used to form a fine pattern of a photoresist using a high energy light source such as EUV.

### BRIEF DESCRIPTION OF THE DRAWING

The drawing is a cross-sectional view showing one or more acts of a method of forming patterns using a resist topcoat composition according to one or more embodiments of the present disclosure.

### DETAILED DESCRIPTION

Embodiments of the present disclosure will hereinafter be described in more detail, and may be easily performed by a person skilled in the art. However, this disclosure may be embodied in many different forms and is not construed as limited to the embodiments set forth herein.

In the drawing, the thickness of layers, films, panels, regions, etc., may be exaggerated for clarity and like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

As used herein, when a definition is not otherwise provided, “substituted” refers to replacement of a hydrogen atom of a compound or a functional group by a substituent selected from a halogen atom (F, Br, Cl, and/or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and combinations thereof.

As used herein, when a definition is not otherwise provided, “hetero” refers to a group including 1 to 10 heteroatoms selected from N, O, S, and P.

In addition, in the present specification, the acrylic polymer refers to an acrylic polymer and/or a methacrylic polymer.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is Shodex LF-804, standard sample is Shodex polystyrene).

In addition, unless otherwise defined in the specification, “*” indicates a linking point of a structural unit or a compound moiety of a compound.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list.

As used herein, the term “and/or” includes any and all combinations of one or more of the associated listed items. Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinafter, a resist topcoat composition according to one or more embodiments is described.

One or more aspects of embodiments of the present disclosure relate to a resist topcoat composition capable of improving photoresist patterning by adding a simple process during the fine pattern forming process of photolithography using (e.g., utilizing) a short-wavelength light source (such as an ArF excimer laser (wavelength: 193 nm)) and/or high energy rays (such as extreme ultraviolet (EUV; wavelength: 13.5 nm)) to remove or reduce SLO defects in the resist pattern, and a method for forming a photoresist pattern using such a topcoat.

The resist topcoat composition according to one or more embodiments includes an acrylic polymer including a structural unit containing a hydroxy group and a fluorine; at least one acid compound selected from a sulfonic acid compound containing at least one fluorine, a sulfonimide compound containing at least one fluorine, and a carboxylic acid compound containing at least one fluorine; and a solvent.

The composition according to the embodiments is coated on the photoresist (e.g., on the preliminary photoresist), and has excellent (or improved) solubility in a solvent having low reactivity to the photoresist, so that it may be easily (or suitably) removed together with the removal of the SLO defects, which is advantageous for realizing high resolution.

The formation and removal of the resist topcoat may be performed by a relatively simple process, which is advantageous in terms of process economy, and the yield may be improved due to the removal of the SLO defects.

Because the acrylic polymer included in the composition contains a hydroxy group and fluorine in the structural unit at the same time, it has excellent (or improved) solubility in a solvent, may be uniformly (or substantially uniformly) coated on a pattern, and may minimize (or reduce) the influence on the resist.

In addition, the acid compound included in the composition is an acid compound containing at least one fluorine, and may be, for example, selected from a sulfonic acid compound containing at least one fluorine, a sulfonimide compound containing at least one fluorine, and a carboxylic acid compound containing at least one fluorine.

As described above, as the acid compound containing at least one fluorine is added, defect portions of the resist may be selectively removed.

Therefore, by using the composition for a resist upper layer film according to one or more embodiments, a high-resolution pattern can be obtained with a high yield.

The acrylic polymer and the acid compound may be included in a weight ratio of about 3:1 to about 30:1, for example, about 3:1 to about 25:1.

By including the acrylic polymer and the acid compound in the above weight ratio, the resist topcoat composition according to one or more embodiments may provide a resist topcoat for easy removal of SLO defects.

A total weight of the acrylic polymer and the acid compound may be about 0.1 wt % to about 10 wt % based on the total weight of the resist topcoat composition. Within the above range, the resist topcoat may be easily (or suitably) removed.

For example, the acrylic polymer may include a structural unit represented by Chemical Formula 1:

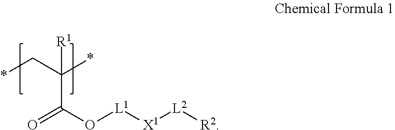

In Chemical Formula 1,

R¹ is hydrogen or a substituted or unsubstituted C1 to C10 alkyl group,

R² is hydrogen, fluorine, a hydroxy group, or a substituted or unsubstituted C1 to C20 alkyl group,

L¹ and L² are each independently a single bond, or a substituted or unsubstituted C1 to C10 alkylene group,

X¹ is a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group),

R², L¹, and L² together include a fluorine and a hydroxy group, and

* is a linking point.

The statements that R², L¹, and L² together include a fluorine and a hydroxy group may mean that:

R² is a C1 to C10 alkyl group substituted with at least one fluorine and at least one hydroxy group, or

at least one selected from L¹ and L² is a C1 to C10 alkylene group substituted with at least one fluorine and at least one hydroxy group, or

one selected from L¹ and L² is a C1 to C10 alkylene group substituted with at least one fluorine and the other is a C1 to C10 allylene group substituted with at least one hydroxy group, or

R² is a fluorine and at least one selected from L¹ and L² is a C1 to C10 alkylene group substituted with a hydroxy group, or

R² is a hydroxy group and at least one selected from L¹ and L² is a C1 to

C10 alkylene group substituted with a fluorine, or

R² is a C1 to C10 alkyl group substituted with a C1 to C10 alkyl group substituted with at least one hydroxy group and at least one fluorine.

For example, the acrylic polymer may include a structural unit represented by Chemical Formula 2:

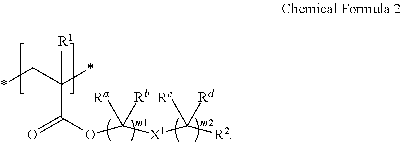

In Chemical Formula 2,

R¹ is hydrogen or a substituted or unsubstituted C1 to C10 alkyl group,

R^{a}, R^{b}, R^{c}, R^{d}, and R² are each independently hydrogen, a fluorine, a hydroxy group, or a substituted or unsubstituted C1 to C20 alkyl group,

m1 and m2 are each independently an integer from 1 to 10,

X¹ is a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group),

R^{a}, R^{b}, R^{c}, R^{d}, and R² together include a fluorine and a hydroxy group, and

* is a linking point.

The statements that R^{a}, R^{b}, R^{c}, R^{d}, and R² together include a fluorine and a hydroxy group may mean that:

at least one selected from R^{a}, R^{b}, R^{c}, R^{d}, and R² is each independently a C1 to C10 alkyl group substituted with a hydroxy group and a fluorine, or

at least one selected from R^{a}, R^{b}, R^{c}, R^{d}, and R² is each independently a C1 to C10 alkyl group substituted with a C1 to C10 alkyl group substituted with a hydroxy group and a fluorine, or

at least one selected from R^{a}, R^{b}, R^{c}, R^{d}, and R² is a fluorine and at least one of the remaining groups is a hydroxy group, or

at least one selected from R^{a}, R^{b}, R^{c}, R^{d}, and R² is a fluorine and at least one of the remaining groups is a C1 to C10 alkyl group substituted with a hydroxy group, or

at least one selected from R^{a}, R^{b}, R^{c}, R^{d}, and R² is a hydroxy group and at least one of the remaining groups is a C1 to C10 alkyl group substituted with a fluorine, or

at least one selected from R^{a}, R^{b}, R^{c}, R^{d}, and R² is a C1 to C20 alkyl group substituted with a fluorine and at least one of the remaining groups is a C1 to C20 alkyl group substituted with a hydroxy group.

For example, R¹ may be hydrogen or a methyl group,

X¹ may be a single bond or —O—, and

R² may be a fluorine, a hydroxy group, a C1 to C10 alkyl group substituted with at least one fluorine, or a C1 to C10 alkyl group substituted with at least one hydroxy group.

For example, R^{c}, R^{d}, and R² of Chemical Formula 2 may together include a fluorine and a hydroxy group.

For example, at least one selected from R^{c} and R^{d} in Chemical Formula 2 may be a fluorine or a C1 to C10 alkyl group substituted with at least one fluorine, and

R² may be a hydroxy group or a C1 to C10 alkyl group substituted with at least one hydroxy group.

For example, at least one selected from R^{c} and R^{d} in Chemical Formula 2 may be a hydroxy group or a C1 to C10 alkyl group substituted with at least one hydroxy group, and R² may be a fluorine or a C1 to C10 alkyl group substituted with at least one fluorine.

For example, in Chemical Formula 2, R^{c} may be a hydroxy group or a C1 to C10 alkyl group substituted with at least one hydroxy group, R^{d} may be a fluorine or a C1 to C10 alkyl group substituted with at least one fluorine, and R² may be a hydroxy group, a fluorine, or a C1 to C10 alkyl group substituted with at least one fluorine or at least one hydroxy group.

For example, at least one selected from R^{c} and R^{d} of Chemical Formula 2 may be a fluorine or a C1 to C10 alkyl group substituted with at least one fluorine, R² may be a hydroxy group, or a C1 to C5 alkyl group substituted with a C1 to C5 alkyl group substituted with at least one hydroxy group and at least one fluorine.

For example, the structural unit containing the hydroxy group and fluorine may be selected from Group I:

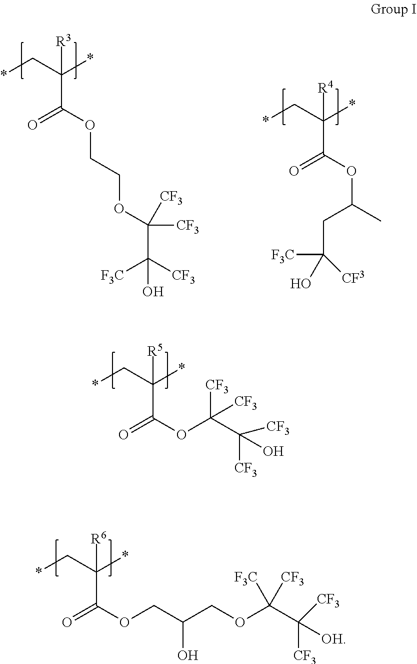

In Group I, R³ to R⁶ are each independently hydrogen or a methyl group, and * is a linking point.

The acrylic polymer may have a weight average molecular weight (Mw) of about 1,000 g/mol to about 50,000 g/mol. For example, it may have a weight average molecular weight of about 2,000 g/mol to about 30,000 g/mol, for example, about 3,000 g/mol to about 20,000 g/mol, or for example, about 4,000 g/mol to about 10,000 g/mol, but not limited thereto. When the weight average molecular weight of the acrylic polymer is within the above range, a carbon content and solubility in a solvent of the resist topcoat composition including the polymer may be optimized or improved.

For example, the acid compound may be at least one of compounds represented by Chemical Formula 3 to Chemical Formula 6:

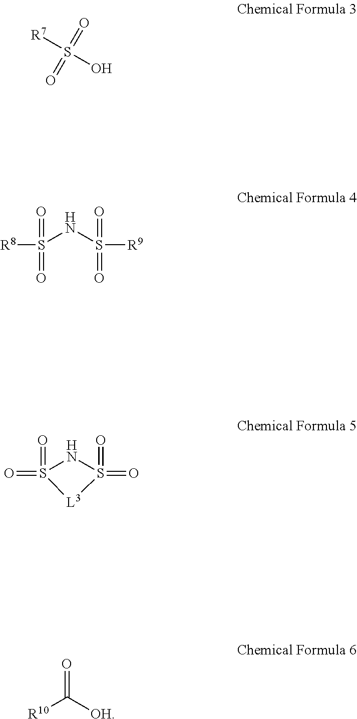

In Chemical Formula 3 to Chemical Formula 6,

R⁷ to R¹⁰ are each independently a fluorine, a C1 to C20 alkyl group substituted with at least one fluorine, a C2 to C20 alkenyl group substituted with at least one fluorine, a C2 to C20 alkynyl group substituted with at least one fluorine, a C3 to C20 cycloalkyl group substituted with at least one fluorine, a C3 to C20 cycloalkenyl group substituted with at least one fluorine, a C3 to C20 cycloalkynyl group substituted with at least one fluorine, a C6 to C20 aryl group substituted with at least one fluorine, or a C1 to C20 heteroaryl group substituted with at least one fluorine, and

L³ is a C1 to C10 alkylene group substituted with at least one fluorine, a C3 to C20 cycloalkylene group substituted with at least one fluorine, a C6 to C20 arylene group substituted with at least one fluorine, or a C1 to C20 heteroarylene group substituted with at least one fluorine.

For example, R⁷ to R¹⁰ in Chemical Formula 3 to Chemical Formula 6 may each independently be a C1 to C10 alkyl group substituted with at least one fluorine, or a C6 to C20 aryl group substituted with at least one fluorine, and

L³ may be a C1 to C5 alkylene group substituted with at least one fluorine.

For example, the acid compound may be at least one of the compounds of Group II:

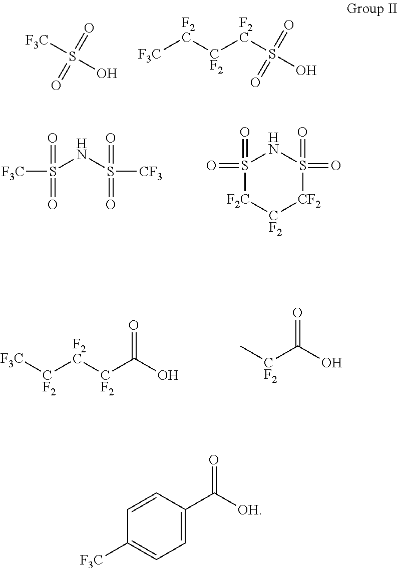

In one or more embodiments, the resist topcoat composition may further include at least one other polymer selected from an acrylic resin, an epoxy-based resin, a novolac-based resin, a glycoluril-based resin, and a melamine-based resin, but is not limited thereto.

The resist topcoat composition may further include an additive including a surfactant, a thermal acid generator, a plasticizer, or a combination thereof.

The surfactant may be, for example, an alkylbenzenesulfonic acid salt, an alkylpyridinium salt, polyethylene glycol, a quaternary ammonium salt, and/or the like, but is not limited thereto.

The thermal acid generator may be, for example, an acid compound (such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalene carboxylic acid, benzointosylate, 2-nitrobenzyl tosylate, and/or one or more other suitable organic sulfonic acid alkyl esters), but is not limited thereto.

The additive may be included in an amount of about 0.001 to about 40 parts by weight based on 100 parts by weight of the resist topcoat composition. Within the above range, solubility may be improved without substantially changing the optical properties of the resist topcoat composition.

The solvent may be an ether-based solvent represented by Chemical Formula 7:

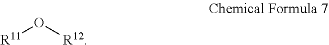

In Chemical Formula 7,

R¹¹ and R¹² are each independently a substituted or unsubstituted C3 to C20 alkyl group.

For example, the ether-based solvent may be selected from diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, 2-octanone, 4-heptanone, and combinations thereof.

The ether-based solvent may have sufficient (or suitable) solubility and/or dispersibility for the composition of the present embodiments.

According to one or more other embodiments, a photoresist pattern may be prepared using the resist topcoat composition of the present embodiments. The resist topcoat may be in a form of a cured film obtained through a heat treatment process after coating the resist topcoat composition on, for example, a preliminary photoresist pattern.

Hereinafter, a method of forming patterns using the resist topcoat composition of the present embodiments is described with reference to the drawing.

A method of forming patterns according to one or more embodiments includes forming a preliminary photoresist pattern on a substrate (act (1) in the drawing), coating the resist topcoat composition on the preliminary photoresist pattern, drying and heating the substrate on which the resist topcoat composition is coated to form a topcoat (act (2) in the drawing), and spraying a rinse solution on the substrate coated with the topcoat to remove the topcoat (act (3) in the drawing).

The forming of the photoresist pattern on a substrate (1) may include coating a semiconductor resist composition on the substrate 100 by spin coating, slit coating, inkjet printing, etc., and drying and heat treating the coated semiconductor resist composition to form a photoresist film 101, selectively exposing and developing the photoresist film 101 to dissolve and remove the photoresist film corresponding to the exposed area to form a preliminary photoresist pattern 102a.

The forming of the preliminary photoresist pattern 102a may be performed by any suitable method, and details thereof will not be provided.

In the preliminary photoresist pattern 102a formed according to the above-described method, the bridge 10 connected to the adjacent pattern (e.g., adjacent portion of the preliminary photoresist pattern 102a) and the scum 20 remaining in the gap between adjacent portions of the pattern may occur, and these defects may cause SLO defects in the thin film pattern to be formed later thus causing a decrease of yield.

In the method of forming patterns according to one or more embodiments of the present disclosure, in order to remove the bridge 10 and the scum 20 after the preliminary photoresist pattern 102a is formed, the method may further include coating the resist topcoat composition the preliminary photoresist pattern 102a; drying and heating the substrate coated with the resist topcoat composition to form a topcoat 30 (2); and spraying a rinse solution on the substrate coated with the topcoat 30 to remove the topcoat 30 (3).

The heating of the substrate coated with the resist topcoat composition may be performed at a temperature of about 100° C. to about 500° C.

In the removing of the topcoat 30 by spraying a rinse solution, a solvent having low reactivity with respect to the photoresist and high solubility with respect to the topcoat may be advantageous, and the solvent according to the present embodiments may be used.

As such, in the photoresist pattern 102b formed after performing the coating of the topcoat 30 (2) and the removing of the topcoat 30 (3), the bridge 10 and the scum 20 may be removed compared with the preliminary photoresist pattern 102a formed before performing the processes (2) and (3), so that the patterning of the photoresist may be improved.

The thin film pattern 103 may be finally formed through a process (act (4) in the drawing) of etching the exposed thin film of the substrate 100 by applying the photoresist pattern 102b as an etching mask, and in the thin film pattern formed in this way, SLO defects may be effectively (or suitably) removed without loss (or substantially without loss) of the fine pattern.

The thin film may be etched, for example, by dry etching using an etching gas, and the etching gas may be, for example, CHF₃, CF₄, Cl₂, BCl₃, or a mixture thereof.

In the exposure process described, the thin film pattern formed using the photoresist pattern 102b that is formed by the exposure process performed using the EUV light source may have a width corresponding to that of the photoresist pattern 102b. For example, the photoresist pattern 102b may have a width of about 5 nm to about 100 nm. For example, the thin film pattern 103 formed from the photoresist pattern 102b that is formed by the exposure process performed using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, like the photoresist pattern 102b, and in some embodiments, may be, for example, less than or equal to about 20 nm in width.

Hereinafter, the present disclosure will be described in more detail through examples relating to the synthesis of the aforementioned polymer and the preparation of a resist topcoat composition including the same. However, the present disclosure is not limited to or by the following examples.

### SYNTHESIS EXAMPLES

### Synthesis of Acrylic Polymer

### Synthesis Example 1: Synthesis of Monomer

20 g (59.86 mmol) of hexafluoro-2,3-bis(trifluoromethyl)-2,3-butanediol(perfluoropinacol), 7.79 g (59.86 mmol) of 2-(hydroxyethyl)methacrylate, and 18.84 g (71.84 mmol) of triphenylphosphine (Ph₃P) were mixed in 110 ml of diethylether under a nitrogen atmosphere and then stirred. After stirring for 30 minutes, the mixture was cooled down to 0° C., and another mixture of 14.52 g (71.84 mmol) of diisopropylazodicarboxylate (DIAD) and 35 ml of diethylether was slowly added thereto over 2 hours. Subsequently, the obtained mixture was stirred at room temperature for 24 hours and then, concentrated. The concentrated mixture was dissolved in dichloromethane and then, treated through column chromatography by using silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate represented by Chemical Formula 1a.

* ¹H-NMR (Acetone-d₆): δ1.90 (3H, t), 4.36 (4H, m), 5.63 (1H, t), 6.09 (1H, t), 8.34 (1H,$)

* ¹⁹F-NMR (Acetone-d₆): δ−70.12 (6F, m), −65.38 (6F, m)

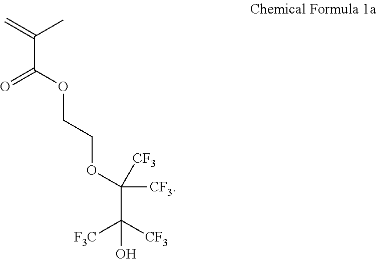 [SMILES: C=C(C)C(=O)OCCOC(C(F)(F)F)(C(F)(F)F)C(O)(C(F)(F)F)C(F)(F)F]

### Synthesis Example 2: Preparation of Polymer P1

The compound represented by Chemical Formula 1a (37.5 g, 84.0 mmol) according to Synthesis Example 1, dimethyl 2,2′-azobis(2-methylpropionate) (2.5 g, 10.9 mmol, Wako Chemicals, Inc.), and diisoamyl ether (DIAE, 60 g) as monomers were put in a 500 mL 2-necked round flask under a nitrogen atmosphere, and a condenser was connected thereto. After increasing the temperature to 110° C., the obtained mixture was reacted for 24 hours, and the reaction solution was cooled down to room temperature. The reaction solution was dropped into a 1 L wide-mouth bottle containing 225 g of heptane, while stirred, producing gum, and then, a supernatant was removed therefrom. After dissolving the remaining gum in 40 g of DIAE, 180 g of heptane was added thereto to form precipitates, and a supernatant was removed therefrom, which was three times repeated to remove monomolecules (e.g., monomers) and oligomers.

As a result, 22.5 g of a polymer P1 including a structural unit represented by

Chemical Formula 1b (a weight average molecular weight: 4,500) was obtained.

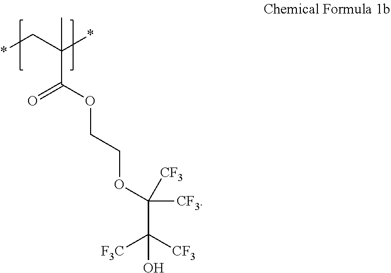

In Chemical Formula 1b, * is a linking point.

### Preparation of Resist Topcoat Composition

### Examples 1 to 7 and Comparative Examples 1 to 4

Each resist topcoat composition according to Examples 1 to 7 and Comparative Examples 1 to 4 was prepared by mixing the acrylic polymer P1 according to Synthesis Example 2, a mixture including the acid compounds represented by A1 to A11, and diisoamylether (DIAE) in compositions shown in Table 1, stirring the mixture at room temperature of 23° C. for 24 hours, and filtering it with a TEFLON (tetrafluoroethylene) filter having a pore size of 0.45 μm.

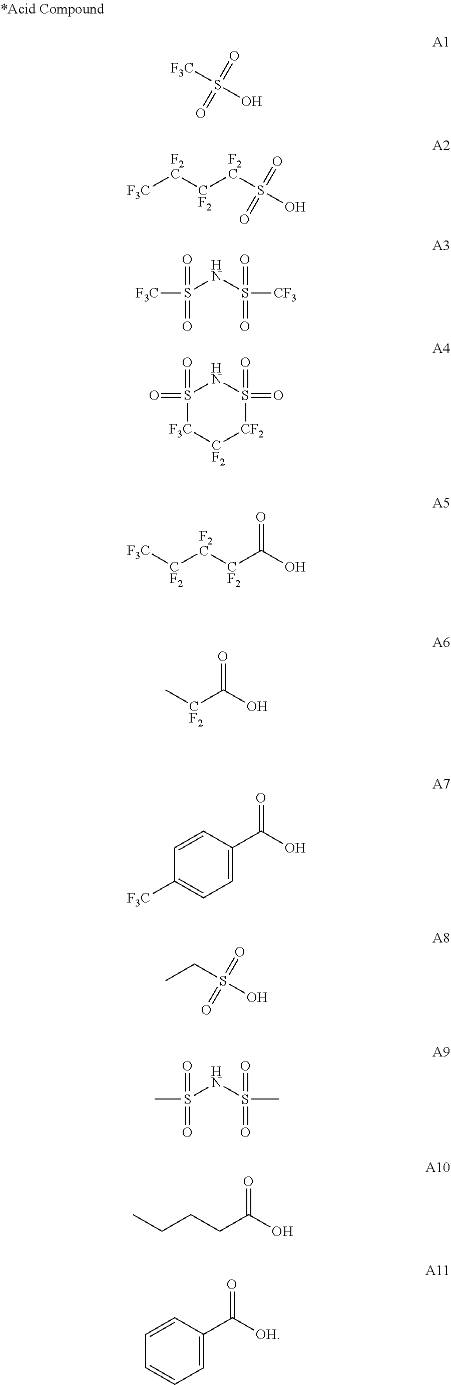

TABLE 1

| | Acid compound | | Acrylic polymer | | Solvent | |
|---|---|---|---|---|---|---|
| | | Content | | Content | | Content |
| Composition | Compound | (wt %) | Compound | (wt %) | Compound | (wt %) |
| Example 1 | A1 | 0.2 | P1 | 4.3 | DIAE | 95.5 |
| Example 2 | A2 | 0.4 | P1 | 4.3 | DIAE | 95.3 |
| Example 3 | A3 | 0.4 | P1 | 4.3 | DIAE | 95.3 |
| Example 4 | A4 | 0.4 | P1 | 4.3 | DIAE | 95.3 |
| Example 5 | A5 | 1.3 | P1 | 4.3 | DIAE | 94.4 |
| Example 6 | A6 | 0.9 | P1 | 4.3 | DIAE | 94.8 |
| Example 7 | A7 | 1.3 | P1 | 4.3 | DIAE | 94.4 |
| Comparative | A8 | 0.2 | P1 | 4.3 | DIAE | 95.5 |
| Example 1 | | | | | | |
| Comparative | A9 | 0.4 | P1 | 4.3 | DIAE | 95.3 |
| Example 2 | | | | | | |
| Comparative | A10 | 1.3 | P1 | 4.3 | DIAE | 94.4 |
| Example 3 | | | | | | |
| Comparative | A11 | 1.3 | P1 | 4.3 | DIAE | 94.4 |
| Example 4 | | | | | | |

### Evaluation 1: Evaluation of Solubility

Each photoresist topcoat composition according to Examples 1 to 7 and Comparative Examples 1 to 4 was prepared and stirred for 24 hours and then, observed with naked eyes to check whether or not precipitates were produced, and the results are shown in Table 2, in which:

(No precipitation—Solubility O; with precipitation—Solubility X)

### Evaluation 2: Evaluation of Non-Pattern Wafer (NPW) Strip

Each photoresist topcoat composition was spin-on coated on a silicon substrate coated with a photoresist and then, heat-treated on a hot plate at 110° C. for 1 minute, forming an about 50 nm-thick topcoat for a photoresist. Subsequently, the substrate coated with the topcoat was rinsed with a rinse solution (diisoamylether (DIAE)), heat-treated on a hot plate at 110° C. for 1 minute and then, measured with respect to a thickness change of the photoresist, which was used to calculate an NPW strip according to the following equation, and the results are shown in Table 2:

(NPW strip=PR thickness (nm) after forming and rinsing a photoresist topcoat−initial PR thickness (nm)).

### Evaluation 3: Evaluation of SLO Defects

On a 12 inch silicon substrate, a lower SiON film, a spin-on carbon film, and a topcoat were sequentially formed. On the SiON film, a 1:1 line/space photoresist pattern with a pitch of 36 nm was formed by an EUV lithography method. The photoresist pattern was transferred into the lower SiON film through dry etching using plasma. Then, all defects including bridge defects between the line patterns were inspected with a defect analysis equipment using a deep ultraviolet (DUV) laser. The detected defects were classified by using SEM, providing the number of the detected defects per unit area (ea/cm²).

Herein, when the number of SLO defects without using the photoresist topcoat compositions was converted into 100, ‘o’ was given to a case in which the number of defects was less than or equal to 80%, and ‘X’ was given to a case in which the number of defects was greater than 80%.

TABLE 2

| | Solubility | NPW strip | SLO Defects |
|---|---|---|---|
| Example 1 | ◯ | −3.0 | ◯ |
| Example 2 | ◯ | −2.8 | ◯ |
| Example 3 | ◯ | −3.4 | ◯ |
| Example 4 | ◯ | −2.9 | ◯ |
| Example 5 | ◯ | −2.5 | ◯ |
| Example 6 | ◯ | −2.7 | ◯ |
| Example 7 | ◯ | −2.6 | ◯ |
| Comparative Example 1 | ◯ | −1.0 | X |
| Comparative Example 2 | ◯ | −0.8 | X |
| Comparative Example 3 | ◯ | −0.5 | X |
| Comparative Example 4 | X | — | — |

Referring to Table 2, when the resist topcoat compositions of Examples 1 to 7 were applied, compared with when the resist topcoat compositions of Comparative Examples 1 to 3 were applied, excellent solubility, NPW strip (effective (or suitable) when in a range of −5.0 nm to −2.5 nm), and defect improvement effects were exhibited.

In addition, in the case of the resist topcoat composition according to Comparative Example 4, the solubility in the rinse solution was not good, so it was impossible to evaluate whether the NPW strip and defects were improved.

Hereinbefore, the certain embodiments of the present disclosure have been described and illustrated, however, it is apparent to a person with ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure and their equivalents.

### DESCRIPTION OF SYMBOLS

1: act of forming a preliminary photoresist pattern on a substrate
2: act of coating the resist topcoat composition on the preliminary photoresist pattern and drying and heating the substrate on which the resist topcoat composition is coated to form a topcoat
3: act of spraying a rinse solution on the substrate coated with the topcoat to remove the topcoat
4: act of etching the exposed thin film by applying the formed photoresist pattern as an etching mask
10: bridge 20: scum
30: topcoat
100: substrate 101: photoresist film
102a: preliminary photoresist pattern formed before performing coating and removing the topcoat
102b: photoresist pattern formed after performing coating and removing the topcoat
103: thin film pattern

What is claimed is:

1. A resist topcoat composition comprising:
an acrylic polymer comprising a structural unit comprising a hydroxy group and a fluorine;
at least one acid compound selected from a sulfonic acid compound comprising at least one fluorine, a sulfonimide compound comprising at least one fluorine, and a carboxylic acid compound comprising at least one fluorine; and
a solvent.

2. The resist topcoat composition of claim 1, wherein the acrylic polymer and the acid compound are in a weight ratio of about 3:1 to about 30:1.

3. The resist topcoat composition of claim 1, wherein a total weight of the acrylic polymer and the acid compound is about 0.1 wt % to about 10 wt % based on a total weight of the resist topcoat composition.

4. The resist topcoat composition of claim 1, wherein the acrylic polymer comprises a structural unit represented by Chemical Formula 1: 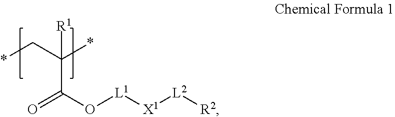
and
wherein, in Chemical Formula 1,
R¹ is hydrogen or a substituted or unsubstituted C1 to C10 alkyl group,
R² is hydrogen, fluorine, a hydroxy group, or a substituted or unsubstituted C1 to C20 alkyl group,
L¹ and L² are each independently a single bond, or a substituted or unsubstituted C1 to C10 alkylene group,
X¹ is a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group), and
R², L¹, and L² together comprise a fluorine and a hydroxy group.

5. The resist topcoat composition of claim 1, wherein the acrylic polymer comprises a structural unit represented by Chemical Formula 2: 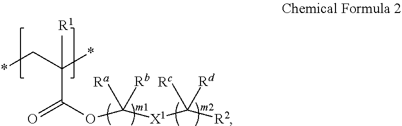
and
wherein, in Chemical Formula 2,
R¹ is hydrogen or a substituted or unsubstituted C1 to C10 alkyl group,
R^{a}, R^{b}, R^{c}, R^{d}, and R² are each independently hydrogen, a fluorine, a hydroxy group, or a substituted or unsubstituted C1 to C20 alkyl group,
m1 and m2 are each independently an integer from 1 to 10,
X¹ is a single bond, —O—, —S—, —S(O)—, —S(O)₂—, —C(O)—, —(CO)O—, —O(CO), —O(CO)O—, or —NR′— (wherein, R′ is hydrogen, deuterium, or a C1 to C10 alkyl group), and
R^{a}, R^{b}, R^{c}, R^{d}, and R² together comprise a fluorine and a hydroxy group.

6. The resist topcoat composition of claim 1, wherein the structural unit comprising the hydroxy group and the fluorine is selected from Group I: 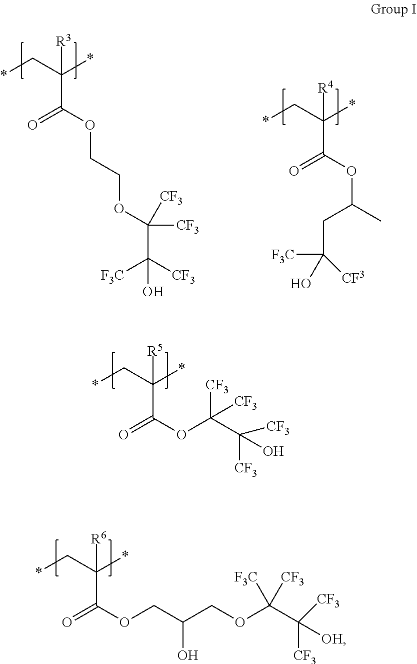
and
wherein, in Group I, R³ to R⁶ are each independently hydrogen or a methyl group, and
* is a linking point.

7. The resist topcoat composition of claim 1, wherein a weight average molecular weight of the acrylic polymer is about 1,000 g/mol to about 50,000 g/mol.

8. The resist topcoat composition of claim 1, wherein the acid compound comprises at least one of compounds represented by Chemical Formula 3 to Chemical Formula 6: 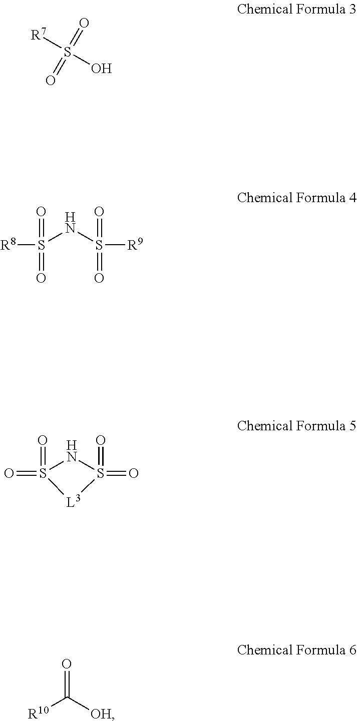
and
wherein, in Chemical Formula 3 to Chemical Formula 6,
R⁷ to R¹⁰ are each independently a fluorine, a C1 to C20 alkyl group substituted with at least one fluorine, a C2 to C20 alkenyl group substituted with at least one fluorine, a C2 to C20 alkynyl group substituted with at least one fluorine, a C3 to C20 cycloalkyl group substituted with at least one fluorine, a C3 to C20 cycloalkenyl group substituted with at least one fluorine, a C3 to C20 cycloalkynyl group substituted with at least one fluorine, a C6 to C20 aryl group substituted with at least one fluorine, or a C1 to C20 heteroaryl group substituted with at least one fluorine, and
L³ is a C1 to C10 alkylene group substituted with at least one fluorine, a C3 to C20 cycloalkylene group substituted with at least one fluorine, a C6 to C20 arylene group substituted with at least one fluorine, or a C1 to C20 heteroarylene group substituted with at least one fluorine.

9. The resist topcoat composition of claim 1, wherein the acid compound is at least one of compounds of Group II:

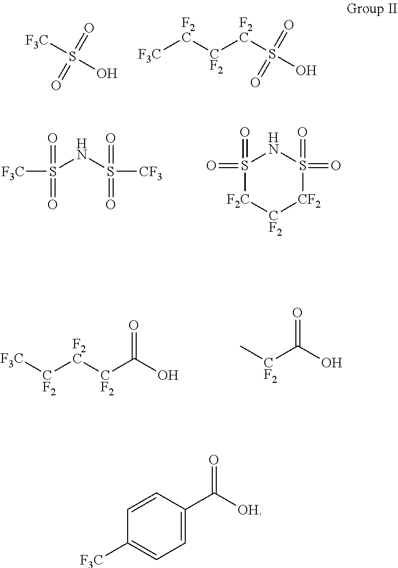

10. The resist topcoat composition of claim 1, wherein the solvent is an ether-based solvent represented by Chemical Formula 7: 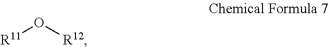
and
wherein, in Chemical Formula 7,
R¹¹ and R¹² are each independently a substituted or unsubstituted C3 to C20 alkyl group.

11. The resist topcoat composition of claim 10, wherein
the ether-based solvent is selected from:
diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, 2-octanone, 4-heptanone, and combinations thereof.

12. A method of forming patterns, the method comprising:
forming a preliminary photoresist pattern on a substrate,
coating the resist topcoat composition of claim 1 on the preliminary photoresist pattern,
drying and heating the substrate on which the resist topcoat composition is coated to form a topcoat, and
spraying a rinse solution on the substrate coated with the topcoat to remove the topcoat.

13. The method of claim 12, wherein the heating of the substrate coated with the resist topcoat composition is performed at a temperature of about 100° C. to about 500° C.
